(19) United States
(12) Patent Application Publication
(10) Pub. No.: US 2013/0235363 A1
(43) Pub. Date: Sep. 12, 2013

(54) DEVICE-SPECIFIC MARKINGS

(71) Applicant: Andreas Doebelt, Dresden (DE)

(72) Inventor: Andreas Doebelt, Dresden (DE)

(73) Assignee: PLASTIC LOGIC LIMITED, Cambridge (GB)

(21) Appl. No.: 13/882,628

(22) PCT Filed: Oct. 31, 2011
(86) PCT No.: PCT/EP2011/069173

§ 371 Date: May 20, 2013

(30) Foreign Application Priority Data
Nov. 1, 2010 (GB) 1018403.4

(51) Int. Cl. G03F 7/20

(52) U.S. Cl. CPC G03F 7/70216
USPC 355/77

(57) ABSTRACT

Producing a plurality of electronic devices by a technique including photolithographically patterning a layer of conductive material (3), and defining at least one device-specific mark (3a) of a respective one of the plurality of devices as part of photolithographically patterning said layer of conductive material.

The present invention relates to the provision of device-specific markings on electronic devices. In one embodiment, the present invention relates to the provision of specific-device markings on device substrates at an early stage of a process of producing electronic devices.

The provision of device-specific markings on device substrates at the early stage of the mass production of electronic devices can be useful for tracking devices during production.

The inventors have identified the challenge of developing a technique for providing device-specific marking at the early stage of the production process which does not create a local height increase, does not generate substantial amounts of debris, and is applicable to devices including heat-sensitive substrates such as plastic substrates.

It is an aim of the present invention to meet this challenge.

The present invention provides a method, comprising: producing a plurality of electronic devices by a technique including photolithographically patterning a layer of material, and defining at least one device-specific mark of a respective one of the plurality of devices as part of photolithographically patterning said layer of material.

The present invention also provides a method comprising: producing a plurality of electronic devices by a technique including patterning a layer of material, wherein the method comprises defining at least one device-specific mark of a respective one of the plurality of devices in said layer of material simultaneously to defining in said layer of material a pattern common to the plurality of devices

According to one embodiment, said pattern common to the plurality of devices defines an array of electronically functional elements.

According to one embodiment, said array of electronically functional elements comprises an array of electrodes for an array of transistors.

According to one embodiment, defining said pattern common to the plurality of devices comprises a first exposure technique by which a mask is used to expose to radiation selected first regions of a photosensitive layer on said layer of material; and wherein defining said device-specific mark comprises a second exposure technique by which selected second regions not exposed to radiation by said first technique are exposed to radiation.

According to one embodiment, exposing said first and second selected regions to radiation changes the solubility of the photosensitive layer in said regions, and further comprising treating the photosensitive layer with a solvent to selectively remove said photosensitive layer in either said first and second selected regions or to selectively remove said photosensitive layer in all unexposed regions; and then using the thus patterned photosensitive layer as a mask to pattern the underlying said layer of material and simultaneously define said common pattern and said device-specific marking in said layer of material.

According to one embodiment, the method further comprises performing said first exposure technique before said second exposure technique.

According to one embodiment, the method further comprises performing said second exposure technique before said first exposure technique.

According to one embodiment, the method further comprises performing said second exposure technique using a laser beam writer.

According to one embodiment, said device-specific mark is one or more selected from the group consisting of a barcode, a matrix code, numerals and text.

According to one embodiment, said layer of material is a layer of conductive material.

Hereunder, an embodiment of the present invention is described in detail, by way of example only, with reference to the accompanying drawings, in which:

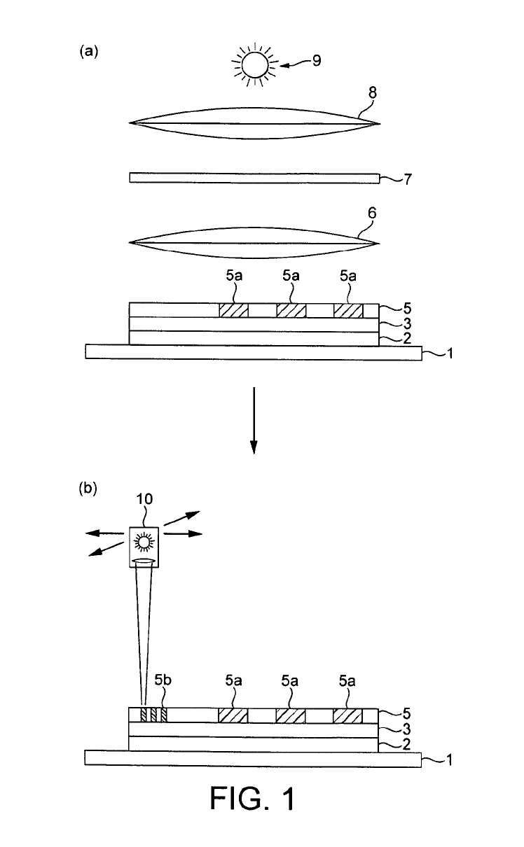

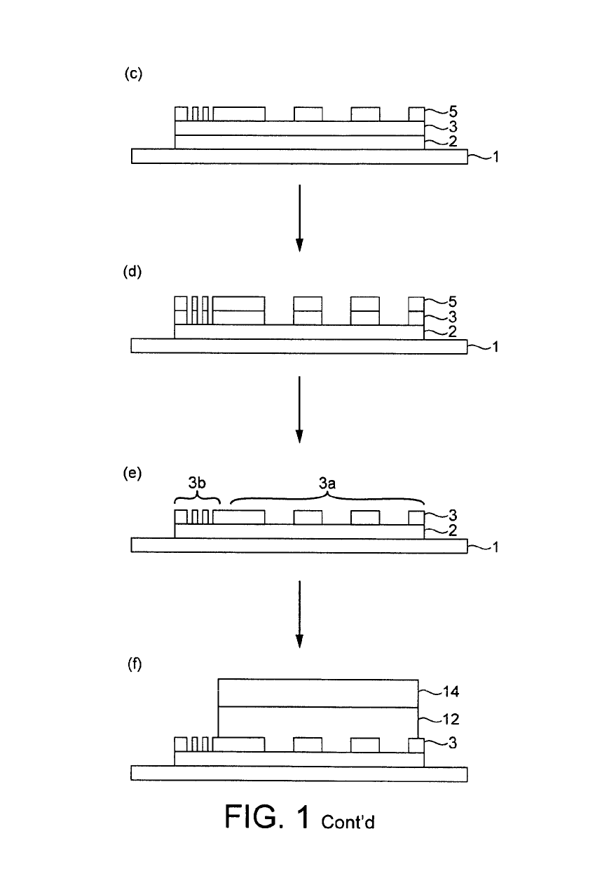

FIG. 1 illustrates a technique in accordance with an embodiment of the present invention.

With reference to FIG. 1, a flexible substrate 2 for an electronic display device is supported on a rigid, glass carrier 1. The flexible substrate comprises an organic polymer base and at least a planarising layer on the upper surface thereof. A thin film 3 of gold noble metal has been deposited on the upper surface of the flexible substrate by a physical vapour deposition technique such as sputtering. Over the thin gold film 3 is provided a blanket layer of positive photoresist material 5. The layer of positive photoresist material 5 is formed by depositing the material in a soluble form from solution, and then baking the thus formed layer to convert it into a less soluble form, which decrease in solubility can be reversed by exposure to ultraviolet (UV) radiation.

With reference to FIG. 1(a), selected portions 5a of the positive resist layer 5 are exposed to UV light using a photomask 7 and lenses 6, 8 to project an image of the photomask 7 on the positive resist layer 5. The selectively exposed portions 5a exhibit increased solubility in a solvent used to later pattern the photoresist layer 5.

The same photomask is used for each device in the mass production of said electronic display devices. The photomask is used to define in the positive photoresist layer 5 a pattern that is used in a subsequent etching step discussed below to define in the gold film 3 electronically-functional elements of the display device, such as source/drain electrodes and signal lines of an array of thin film transistors.

With reference to FIG. 1(b), selected portions 5b of the positive photoresist layer 5 that were not exposed to UV light in the step illustrated in FIG. 1(a) are exposed to UV light using a laser beam writer 10, whose laser beam or group of laser beams can be moved across the photoresist layer 5 in any direction in a plane parallel to the photoresist layer 5. The laser beam writer 10 is also used for each device in the mass production of said electronic display devices, but is used to define in the positive photoresist layer 5 a pattern that is used in a subsequent etching step discussed below to define in the gold film 3 one or more markings unique to the respective device.

With reference to FIG. 1(c), the positive photoresist layer 5 is then treated with a solvent in which the solubility of the irradiated portions of the photoresist material has been increased by exposure to UV light. The irradiated portions 5a and 5b of the photoresist layer 5 are soluble in the solvent and are dissolved and removed upon treatment with the solvent; and the remaining non-irradiated portions of the photoresist layer 5 are substantially insoluble in the solvent, and remain on the surface of the gold film 3.

With reference to FIG. 1(d), the photoresist pattern is then used as a mask for patterning the underlying gold film. In more detail, the resulting structure is exposed to an etchant/solvent that does not dissolve/remove the remaining portions of the photoresist layer 5, but selectively dissolves/removes those portions of the gold film 3 from over which the photoresist material 5 was removed in the earlier steps.

With reference to FIG. 1(e), the now redundant remaining portions of the photoresist material 5 are removed by exposure to UV radiation and treatment with the solvent used in the patterning step illustrated in FIG. 1(c).

With reference to FIG. 1(f), the display device is subsequently completed by forming further elements/layers (whose collective is designated as 12 in FIG. 1(f)) to define an array of thin-film transistors including pixel electrodes at a top surface thereof; and applying to the thus completed backplane a front plane 14 including a display medium such as a liquid crystal display medium or an electrophoretic medium. After completion of the display device, the flexible substrate 2 is released from the rigid carrier 1.

The patterned gold film 3 includes (i) a pattern 3a that is common to each display device and defines electronically-functional elements of the display device, such as source/drain electrodes and signal lines of an array of thin film transistors; and (ii) a pattern 3b that is unique to the respective device. The unique pattern 3b defines a marking that is specific to the respective device, and distinguishes it from other devices. The type, position, size, and resolution of the device-specific markings are configurable. Examples of device-specific markings include datamatrix codes, barcodes, numerals and text. The laser beam writer 10 writes the pattern of the device-specific marking into the photoresist layer 5, and the device-specific marking is detectable in the gold film 3 after the etching step illustrated in FIG. 1(d), because those regions where the gold film 3 has been etched away and the underlying flexible substrate 2 exposed have a contrast to the surrounding regions where the gold film 3 remains intact. This is the case, for example, where the gold film 3 is more reflective than the underlying flexible substrate 2.

The device-specific marking, such as a serial number, can be used for (a) visible confirmation of substrate identification, and (b) automated substrate tracking throughout any subsequent processing, such as deposition/application of the further layers/elements that are needed to complete each display device. The device-specific marking remains in the final product and can also serve as a unique identifier for the final product.

The above-described technique of providing a device-specific marking has the following advantages. The resulting marking has good chemical resistance to process chemicals/solvents of the kind that are used in the production of display devices including one or more organic materials, particularly organic semiconductor materials and gate dielectric materials. There is no risk of generating the kind of potentially damaging debris that could be generated if the markings were formed by laser ablation or mechanical engraving. The technique can provide device-specific marks of high resolution, particularly device-specific marks of higher resolution than can be achieved by mechanical engraving. The device-specific marks are easily accommodated within the device, because they are of the same height as the common metal pattern 3a at the same level. The technique does not generate large amounts of heat in the substrate, which facilitates the use of substrates including organic polymer base layers, which can be favoured for their flexibility.

According to one variation, the step illustrated in FIG. 1(a) is carried out after the step illustrated in FIG. 1(b), i.e. the part of the photolithographic technique using the laser beam writer 10 is carried out before the part of the photolithographic technique using the photomask 7.

We have used the example of patterning a gold film on a flexible polymer substrate to describe a technique in accordance with an embodiment of the present invention, but the same technique is equally applicable, for example, to the incorporation of device-specific markings into other metal films on organic polymer or other substrates.

Also, the drawings illustrate a production technique in which a gold film on a substrate provides electronically-functional elements and a device-specific marking for a single device. However, the above-described technique according to an embodiment of the present invention is also equally applicable to a production technique in which a gold film on a relatively large area sheet of flexible substrate material is patterned in the same way to define common electronically-functional elements and respective device-specific markings for a plurality of devices, and the substrate material sheet is later divided up into a plurality of flexible substrates for the plurality of devices.

In addition to any modifications explicitly mentioned above, it will be evident to a person skilled in the art that various other modifications of the described embodiment may be made within the scope of the invention.

1. A method, comprising: producing a plurality of electronic devices by a technique including photolithographically patterning a layer of material, and defining at least one device-specific mark of a respective one of the plurality of devices as part of photolithographically patterning said layer of material.

2. A method according to claim 1, comprising defining the at least one device-specific mark in said layer of material simultaneously to defining in said layer of material a pattern common to the plurality of devices.

3. A method comprising: producing a plurality of electronic devices by a technique including patterning a layer of material, wherein the method comprises defining in said layer of material at least one device-specific mark of a respective one of the plurality of devices simultaneously to defining in said layer of material a pattern common to the plurality of devices.

4. A method according to claim 3, wherein said pattern common to the plurality of devices defines an array of electronically functional elements.

5. A method according to claim 4, wherein said array of electronically functional elements comprises an array of electrodes for an array of transistors.

6. A method according to claim 3, wherein defining said pattern common to the plurality of devices comprises a first exposure technique by which a mask is used to expose to radiation selected first regions of a photosensitive layer on said layer of material; and wherein defining said device-specific mark comprises a second exposure technique by which selected second regions not exposed to radiation by said first technique are exposed to radiation.

7. A method according to claim 6, wherein exposing said first and second selected regions to radiation changes the solubility of the photosensitive layer in said regions, and further comprising treating the photosensitive layer with a solvent to selectively remove said photosensitive layer in either said first and second selected regions or to selectively remove said photosensitive layer in all unexposed regions; and then using the thus patterned photosensitive layer as a mask to pattern the underlying said layer of material and simultaneously define said common pattern and said device-specific marking in said layer of material.

8. A method according to claim 6, comprising performing said first exposure technique before said second exposure technique.

9. A method according to claim 6, comprising performing said second exposure technique before said first exposure technique.

10. A method according to claim 6, comprising performing said second exposure technique using a laser beam writer.

11. A method according to claim 1, wherein said device-specific mark is one or more selected from the group consisting of a barcode, a matrix code, numerals and text.

12. A method according to claim 1, wherein said layer of material is a layer of conductive material.

13. A method according to claim 3, wherein said device-specific mark is one or more selected from the group consisting of a barcode, a matrix code, numerals and text.

14. A method according to claim 1, wherein said layer of material is a layer of conductive material.

15. A method according to claim 7, comprising performing said second exposure technique before said first exposure technique.
